(19) United States
(12) Patent Application Publication
(10) Pub. No.: US 2014/0244203 A1
(43) Pub. Date: Aug. 28, 2014

(54) TESTING SYSTEM AND METHOD OF INTER-INTEGRATED CIRCUIT BUS

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: HAO HU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/083,605

(22) Filed: Nov. 19, 2013

(30) Foreign Application Priority Data
Feb. 27, 2013 (CN) 2013100618584

(51) Int. Cl. G01R 31/28

(52) U.S. Cl. CPC G01R 31/2801
USPC 702/118

(57) ABSTRACT

A testing system configured to test real-time signals of an I²C bus of a motherboard includes an oscillograph and a testing device. The motherboard comprises an I²C master control device and an I²C slave device connected to the I²C master control device by the I²C bus. The oscillograph is connected to the I²C bus and configured to collect the real-time signals of the I²C bus. The testing device is connected to the motherboard and the oscillograph. The testing device is configured to send a testing command to start the I²C master control device and determine whether the real-time signals comply with predetermined parameters. The testing device is further configured to generate a testing report depicting whether the real-time signals comply with the predetermined parameters.

### BACKGROUND

1. Technical Field

The disclosure generally relates to testing systems and methods, and particularly to a testing system and method for an inter-integrated circuit bus (I²C).

2. Description of Related Art

I²C buses are widely used for serial data communication between multiple devices. Real-time signals transmitted by the I²C bus are manually tested by using an oscillograph. However, manually testing the I²C bus using the oscillograph may not be accurate or efficient.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the views.

FIG. 1 is a block diagram of one embodiment of a testing system comprising a motherboard.

FIG. 2 shows a flowchart of one embodiment of a method for testing real-time signals transmitted by an I²C bus.

### DETAILED DESCRIPTION

The disclosure is illustrated by way of example and not by way of limitation in the figures of the accompanying drawings, in which like reference numerals indicate similar elements. It should be noted that references to “an” or “one” embodiment in this disclosure are not necessarily to the same embodiment, and such references can mean “at least one.”

In general, the word “module,” as used herein, refers to logic embodied in hardware or firmware, or to a collection of software instructions, written in a programming language such as Java, C, or assembly. One or more software instructions in the modules may be embedded in firmware, such as in an erasable-programmable read-only memory (EPROM). The modules described herein may be implemented as either software and/or hardware modules and may be stored in any type of non-transitory computer-readable medium or other storage device. Some non-limiting examples of non-transitory computer-readable media are compact discs (CDs), digital versatile discs (DVDs), Blu-Ray discs, Flash memory, and hard disk drives.

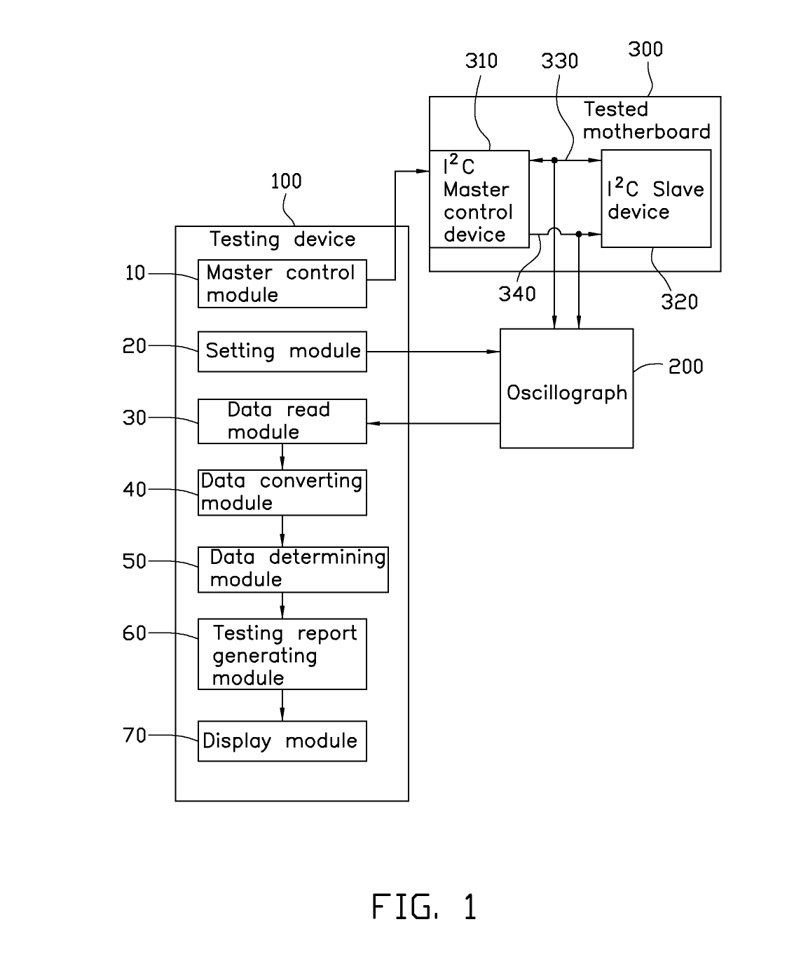

FIG. 1 shows a block view of one embodiment of a testing system for testing transmission of real-time signals of an I²C bus of a motherboard 300. The testing system includes a testing device 100 and an oscillograph 200 connected to the testing device 100. The tested motherboard 300 may be applied in a host computer, a server computer, a tablet computer, or the like.

The tested motherboard 300 includes an I²C master control device 310 and an I²C slave device 320 connected to the I²C master device 310 by the I²C bus. The I²C bus includes a Serial Data (SDA) line 330 and a Serial Clock (SCL) line 340. In one embodiment, the I²C master control device 310 is a central processing unit (CPU), and the I²C slave device is a register. The oscillograph 200 detects real-time signals of the SDA line 330 and the SCL line 340.

The testing device 100 includes a master control module 10, a setting module 20, a data read module 30, a data converting module 40, a data determining module 50, a testing report generating module 60, and a display module 70.

The master control module 10 sends a testing command to the I²C master control device 310 to turn on the tested motherboard 300, so that the I²C master control device 310 can send the real-time signals to the I²C slave device 320 through the SDA line 330 and the SCL line 340. The setting module 20 sets predetermined parameters, such as a unit voltage value, an original position, and a trigger condition, of the oscillograph 200. The oscillograph 200 collects the real-time signals of the I²C bus. The data read module 30 reads the real-time signals collected by the oscillograph 200. The data converting module 40 converts the real-time signals into accessible data, such as binary code. The data determining module 50 determines whether the accessible data complies with the predetermined parameters. The testing report generating module 60 generates a testing report depicting whether the accessible data complies with the predetermined parameters. The display module 70 displays the testing report on a display device (not shown).

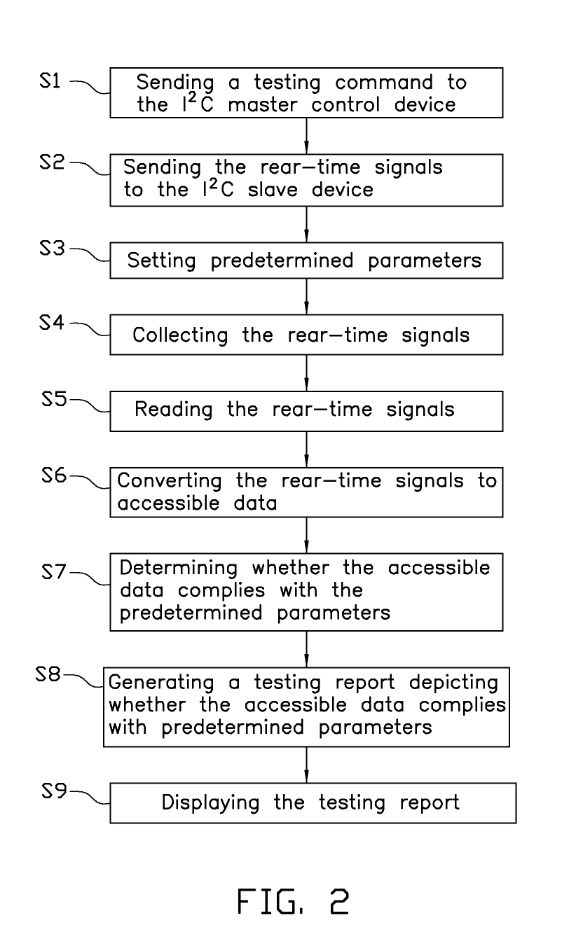

FIG. 2 shows a flowchart of one embodiment of a method for testing real-time signals transmitted by the I²C bus of the tested motherboard 300. The method includes the following steps.

In step S1, the master control module 10 sends a testing command to the I²C master control device 310 to start the I²C master control device 310.

In step S2, the I²C master control device 310 sends the real-time signals to the I²C slave device 320. The real-time signals include serial data and clock data.

In step S3, the setting module 20 sets predetermined parameters of the oscillograph 200.

In step S4, the oscillograph 200 collects the real-time signals of the I²C bus.

In step S5, the data read module 30 reads the real-time signals.

In step S6, the data converting module 40 converts the real-time signals into accessible data, such as binary code.

In step S7, the data determining module 50 determines whether the accessible data complies with the predetermined parameters.

In step S8, the testing report generating module 60 generates a testing report depicting whether the accessible data complies with predetermined parameters.

In step S9, the display module 70 displays the testing report on a display device.

Although numerous characteristics and advantages have been set forth in the foregoing description of embodiments, together with details of the structures and functions of the embodiments, the disclosure is illustrative only, and changes may be made in detail, especially in the matters of arrangement of parts within the principles of the disclosure to the full extent indicated by the broad general meaning of the terms in which the appended claims are expressed.

In particular, depending on the embodiment, certain steps or methods described may be removed, others may be added, and the sequence of steps may be altered. The description and the claims drawn for or in relation to a method may give some indication in reference to certain steps. However, any indication given is only to be viewed for identification purposes, and is not necessarily a suggestion as to an order for the steps.

What is claimed is:

1. A testing system configured to test real-time signals of an Inter Integrated Circuit (I²C) bus of a tested motherboard, the tested motherboard comprising an I²C master control device and an I²C slave device connected to the I²C master control device by the I²C bus, and the testing system comprising:
an oscillograph connected to the I²C bus and configured to collect the real-time signals of the I²C bus; and
a testing device connected to the tested motherboard and the oscillograph; the testing device being configured to send a testing command causing the I²C master control device to send the real-time signals to the I²C slave device, to determine whether the real-time signals complies with predetermined rules, to generate a testing report depicting whether the real-time signals complies with the predetermined rules.

2. The testing system of claim 1, wherein the testing device comprises a master control module connected to the I²C master control device, and the master control module is configured to send the testing command to start the I²C master control device.

3. The testing system of claim 1, wherein the testing device further comprises a setting module connected to the oscillograph, and the setting module is configured to set parameters of the oscillograph.

4. The testing system of claim 3, wherein the testing device further comprises a data read module connected to the oscillograph, and the data read module is configured to read the real-time signals from the oscillograph.

5. The testing system of claim 4, wherein the testing device further comprises a data converting module, and the data converting module is configured to convert the real-time signals to accessible data.

6. The testing system of claim 5, wherein the testing device further comprises a data determining module; and the data determining module is configured to determine whether the accessible data complies with predetermined parameters.

7. The testing system of claim 1, wherein the testing device further comprises a display module; and the display module is configured to display the testing report.

8. The testing system of claim 1, wherein I²C bus comprises a Serial Data (SDA) line and a Serial Clock (SCL) line, and the oscillograph is configured to collect real-time signals of the SDA line and SCL line.

9. A method for testing real-time signals of an Inter Integrated Circuit (I²C) bus of a tested motherboard, and the tested motherboard comprising an I²C master control device and an I²C slave device connected to the I²C master control device by the I²C bus, the method comprising:
sending a testing command causing the I²C master control device to send real-time signals to the I²C slave device;
collecting the real-time signals of the I²C bus by an oscillograph;
determining whether the real-time signals complies with predetermined rules;
generating a testing report depicting whether the real-time signals complies with the predetermined rules; and
displaying the testing report.

10. The method of claim 9, wherein the method further comprises:
setting parameters of the oscillograph.

11. The method of claim 9, wherein the method further comprises:
reading the real-time signals from the oscillograph.

12. The method of claim 10, wherein the method further comprises:
converting the real-time signals to accessible data.

13. The method of claim 12, wherein the method further comprises:
determining whether the accessible data complies with predetermined parameters.

14. The method of claim 8, wherein the I²C bus comprises a Serial Data (SDA) line and a Serial Clock (SCL) line, and the method further comprises:
collecting real-time signals of the SDA line and SCL line.
